(19) United States
(12) Patent Application Publication
(10) Pub. No.: US 2021/0269313 A1
(43) Pub. Date: Sep. 2, 2021

(54) POLYCRYSTALLINE DIAMOND STRUCTURE

(71) Applicant: Element Six Abrasives S.A., Luxembourg (LU)

(72) Inventors: Nedret CAN, Oxfordshire (GB); Kaveshini NAIDOO, Springs (ZA)

(21) Appl. No.: 17/321,777

(22) Filed: May 17, 2021

Related U.S. Application Data
(63) Continuation of application No. 15/955,050, filed on Apr. 17, 2018, now abandoned.
Application No. 15/955,050 is a continuation of application No. 14/407,959, filed on Dec. 14, 2014, now abandoned.
(60) Provisional application No. 61/660,547, filed on Jun. 15, 2012.

(30) Foreign Application Priority Data
Jun. 15, 2012 (GB) 1210678.7

(51) Int. Cl. C01B 32/25; E21B 10/573; B82Y 30/00; B01J 3/06; B32B 18/00; C04B 35/52; C04B 35/626; C04B 35/63; C04B 35/645; C04B 37/02; C22C 26/00; E21B 10/46

(52) U.S. Cl. CPC C01B 32/25; B22F 2005/001; B82Y 30/00; B01J 3/062; B32B 18/00; C04B 35/52; C04B 35/6261; C04B 35/62655; C04B 35/6303; C04B 35/645; C04B 37/021; C22C 26/00; E21B 10/46; B01J 2203/061; B01J 2203/0615; B01J 2203/062; B01J 2203/0625; B01J 2203/0655; B01J 2203/0685; C04B 2235/3813; C04B 2235/3839; C04B 2235/3843; C04B 2235/424; C04B 2235/425; C04B 2235/427; C04B 2235/5436; C04B 2235/5445; C04B 2235/5454; C04B 2235/5472; C04B 2235/96; C04B 2235/9607; C04B 2237/588; C04B 2237/704; B01J 2203/068; E21B 10/573

(57) ABSTRACT

A polycrystalline diamond structure comprises a first region and a second region adjacent the first region, the second region being bonded to the first region by intergrowth of diamond grains. The first region comprises a plurality of alternating strata or layers, each or one or more strata or layers in the first region having a thickness in the range of around 5 to 300 microns. The polycrystalline diamond (PCD) structure has a diamond content of at most about 95 percent of the volume of the PCD material, a binder content of at least about 5 percent of the volume of the PCD material, and one or more of the layers or strata in the first region comprise and/or the second region comprises diamond grains having a mean diamond grain contiguity of greater than about 60 percent and a standard deviation of less than about 2.2 percent. There is also disclosed a method of making such a polycrystalline diamond structure.

### FIELD

This disclosure relates to a polycrystalline diamond (PCD) structure, elements comprising the same, methods for making the same and tools comprising the same, particularly but not exclusively for use in rock degradation or drilling, or for boring into the earth.

### BACKGROUND

PCD material comprises a mass of substantially inter-grown diamond grains and interstices between the diamond grains.

Components comprising PCD are used in a wide variety of tools for cutting, machining, drilling or degrading hard or abrasive materials such as rock, metal, ceramics, composites and wood-containing materials. In particular, cutter inserts comprising PCD material are widely used in drill bits used for boring into the earth in the oil and gas drilling industry. Such cutter inserts for machine and other tools may comprise a layer of polycrystalline diamond (PCD) bonded to a cemented carbide substrate. PCD is an example of a superhard material, also called superabrasive material, which has a hardness value substantially greater than that of cemented tungsten carbide.

PCD comprises a mass of substantially inter-grown diamond grains forming a skeletal mass, which defines interstices between the diamond grains. PCD material comprises at least about 80 volume % of diamond and may be made by subjecting an aggregated mass of diamond grains to an ultra-high pressure of greater than about 5 GPa, typically about 5.5 GPa, and temperature of at least about 1200° C., typically about 1440° C., in the presence of a sintering aid, also referred to as a catalyst material for diamond. Catalyst material for diamond is understood to be material that is capable of promoting direct inter-growth of diamond grains at a pressure and temperature condition at which diamond is thermodynamically more stable than graphite. Some catalyst materials for diamond may promote the conversion of diamond to graphite at ambient pressure, particularly at elevated temperatures. Examples of catalyst materials for diamond are cobalt, iron, nickel and certain alloys including any of these. Interstices within the PCD material may be wholly or partially filled with residual catalyst material. PCD may be integrally formed on and bonded to a cobalt-cemented tungsten carbide substrate, which may provide a source of cobalt catalyst material for sintering the PCD. As used herein, the term “integrally formed” regions or parts are produced contiguous with each other and are not separated by a different kind of material.

Although PCD material is extremely abrasion resistant, there is a need for PCD tool inserts that have enhanced fracture resistance.

### SUMMARY

Viewed from a first aspect, there is provided a polycrystalline diamond structure comprising a first region and a second region adjacent the first region, the second region being bonded to the first region by intergrowth of diamond grains, the first region comprising a plurality of alternating strata or layers, each or one or more strata or layers in the first region having a thickness in the range of around 5 to 300 microns; wherein the polycrystalline diamond (PCD) structure has a diamond content of at most about 95 percent of the volume of the PCD material, a binder content of at least about 5 percent of the volume of the PCD material, and one or more of the layers or strata in the first region comprise and/or the second region comprises diamond grains having a mean diamond grain contiguity of greater than about 60 percent and a standard deviation of less than about 2.2 percent.

Viewed from a second aspect, there is provided a polycrystalline diamond compact or construction comprising the PCD structure defined above.

A PCD element comprising the above PCD structure bonded to a cemented carbide support body may be provided, as well as a tool comprising such a PCD element. The tool may, for example, be a drill bit or a component of a drill bit for boring into the earth, or a pick or an anvil for degrading or breaking hard material such as asphalt or rock.

Viewed from a second aspect there is provided a method for making a polycrystalline diamond (PCD) structure, the method comprising:

providing a first fraction of diamond particles or grains and a sintering additive, the sintering additive comprising a carbon source of nano-sized particles or grains, and forming the diamond particles and sintering additive into a first aggregated mass, providing a second fraction of diamond particles or grains and forming into a second aggregated mass;

consolidating the first aggregated mass and a binder material, typically a catalyst material for diamond and the second aggregated mass to form a green body formed of a plurality of alternating layers or strata of the first and second aggregate masses;

and subjecting the green body to conditions of pressure and temperature at which diamond is more thermodynamically stable than graphite and for a time sufficient to consume the sintering additive, sintering it and forming a body of polycrystalline diamond material that is:

thermodynamically and crystallographically stable,

substantially devoid of any nano-structures, the body of polycrystalline diamond (PCD) material having a diamond content of at most about 95 percent of the volume of the PCD material, a binder content of at least about 5 percent of the volume of the PCD material,

the step of sintering further comprising forming a body of polycrystalline diamond material comprising a first region and a second region adjacent the first region, the second region being bonded to the first region by intergrowth of diamond grains; the first region comprising a plurality of alternating strata or layers, each stratum or layer having a thickness in the range of around 5 to 300 microns; wherein the alternating layers or strata in the first region comprise first layers or strata alternating with second layers or strata, the first layers or strata being in a state of residual compressive stress and the second layers or strata being in a state of residual tensile stress; and wherein and one or more of the layers or strata in the first regions and/or the second region comprise diamond grains having a mean diamond grain contiguity of greater than about 60 percent and a standard deviation of less than about 2.2 percent.

### BRIEF DESCRIPTION OF THE DRAWINGS

Examples of PCD structures will now be described with reference to the accompanying drawings, in which:

FIG. 1 shows a schematic perspective view of an example PCD cutter element for a drill bit for boring into the earth;

FIG. 2 shows a schematic cross-section view of an example of a portion of a PCD structure;

FIG. 3 shows a schematic longitudinal cross-section view of an example of a PCD element;

FIG. 4 shows a schematic longitudinal cross-section view of an example of a PCD element;

FIG. 5 shows a schematic perspective view of part of an example of a drill bit for boring into the earth;

FIG. 6A shows a schematic longitudinal cross-section view of an example of a pre-sinter assembly for a PCD element;

FIG. 6B shows a schematic longitudinal cross-section view of an example of a PCD element;

FIG. 7A, FIG. 7B, FIG. 7C and FIG. 7D show schematic cross-section views of parts of examples of PCD structures; and

The same references refer to the same general features in all the drawings.

### DESCRIPTION

As used herein, polycrystalline diamond (PCD) is a super-hard material comprising a mass of diamond grains, a substantial portion of which are directly inter-bonded with each other and in which the content of diamond is at least about 80 volume percent of the material. In one embodiment of PCD material, interstices between the diamond gains may be at least partly filled with a binder material comprising a catalyst for diamond. As used herein, “interstices” or “interstitial regions” are regions between the diamond grains of PCD material. In examples of PCD material, interstices or interstitial regions may be substantially or partially filled with a material other than diamond, or they may be substantially empty. Examples of PCD material may comprise at least a region from which catalyst material has been removed from the interstices, leaving interstitial voids between the diamond grains. As used herein, a “catalyst material for diamond” is a material capable of promoting the direct intergrowth of diamond grains or particles under conditions of temperature and pressure at which diamond is more thermodynamically stable than graphite.

As used herein, a “green body” is an article that is intended to be sintered or which has been partially sintered, but which has not yet been fully sintered to form an end product. It may generally be self-supporting and may have the general form of the intended finished article.

As used herein, a “superhard wear element” is an element comprising a superhard material and is for use in a wear application, such as degrading, boring into, cutting or machining a workpiece or body comprising a hard or abrasive material.

As used herein, the words “average” and “mean” have the same meaning and are interchangeable.

As used herein, “nanodiamond” and “nano-sized carbon source” are particles or grains that have their major diametric dimension of 0.1 microns (100 nm) or less.

As used herein, UDD is “ultra-dispersed nanodiamond”, consisting of diamond particles of 2-50 nm, and produced by detonation of carbon-containing explosives. UDD particles typically consist of a polycrystalline diamond core surrounded by a metastable (non-diamond) carbon shell.

As used herein, PDD is “polycrystalline detonated diamond powder”, also known as “poly-dispersed diamond” comprising particles that may be as small as 0-50 nm, typically consisting of polycrystalline nanodiamond grains of about 20-25 nm that are produced by shock-wave compression of carbon materials mixed with catalyst. PDD typically contains non-carbon impurities from the catalyst, for example copper.

As used herein, “crushed source nanodiamond” is synthetic (synthesised at HPHT conditions) or natural micron-sized diamond that has been ground, purified and graded to yield nanosized fractions of monocrystalline diamond particles.

As used herein, a PCD grade is a PCD material characterised in terms of the volume content and size of diamond grains, the volume content of interstitial regions between the diamond grains and composition of material that may be present within the interstitial regions. A grade of PCD material according to an embodiment, may be made by a process including providing an aggregate mass of diamond grains having a size distribution suitable for the grade, introducing catalyst material or additive material into the aggregate mass in any of the ways known in the art, and subjecting the aggregated mass in the presence of a source of catalyst material for diamond to a pressure and temperature at which diamond is more thermodynamically stable than graphite and at which the catalyst material is molten. Under these conditions, molten catalyst material may infiltrate from the source into the aggregated mass and is likely to promote direct intergrowth between the diamond grains in a process of sintering, to form a PCD structure. The aggregate mass may comprise loose diamond grains or diamond grains held together by a binder material and said diamond grains may be natural or synthesised diamond grains.

Different PCD grades may have different microstructures and different mechanical properties, such as elastic (or Young's) modulus E, modulus of elasticity, transverse rupture strength (TRS), toughness (such as so-called K₁C toughness), hardness, density and coefficient of thermal expansion (CTE). Different PCD grades may also perform differently in use. For example, the wear rate and fracture resistance of different PCD grades may be different.

The table below shows approximate compositional characteristics and properties of three example PCD grades referred to as PCD grades I, II and Ill. All of the PCD grades may comprise interstitial regions filled with material comprising cobalt metal, which is an example of catalyst material for diamond.

| | PCD | PCD | PCD |
|---|---|---|---|
| | grade I | grade II | grade III |
| Mean grain | 7 | 11 | 16 |
| size, microns | | | |
| Catalyst | 11.5 | 9.0 | 7.5 |
| content, vol. % | | | |
| TRS, MPa | 1,880 | 1,630 | 1,220 |
| K₁C, MPa · m^{1/2} | 10.7 | 9.0 | 9.1 |
| E, GPa | 975 | 1,020 | 1,035 |
| CTE, 10⁻⁶ mm/° C. | 4.4 | 4.0 | 3.7 |

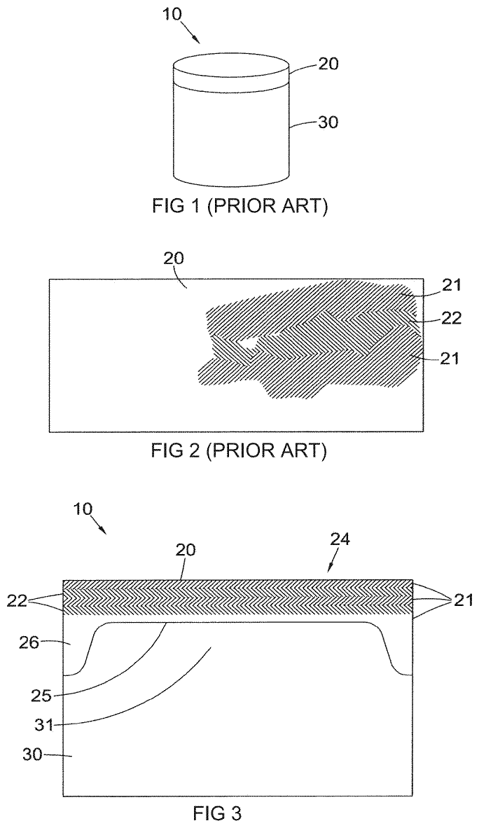

With reference to FIG. 1, an example of a PCD element 10 comprises a PCD structure 20 bonded or otherwise joined to a support body 30, which may comprise cemented tungsten carbide material. The PCD structure 20 comprises one or more PCD grades.

As used herein, the term “stress state” refers to a compressive, unstressed or tensile stress state. Compressive and tensile stress states are understood to be opposite stress states from each other. In a cylindrical geometrical system, the stress states may be axial, radial or circumferential, or a net stress state.

With reference to FIG. 2, an example of a PCD structure 20 comprises at least two spaced-apart compressed regions 21 in compressive residual stress states and at least one tensioned region 22 in a tensile residual stress state. The tensioned region 22 is located between the compressed regions 21 and is joined to them.

Variations in mechanical properties of the PCD material such as density, elastic modulus, hardness and coefficient of thermal expansion (CTE) may be selected to achieve the configuration of a tensioned region between two compressed regions. Such variations may be achieved by means of variations in content of diamond grains, content and type of filler material, size distribution or mean size of the PCD grains, and using different PCD grades either on their own or in diamond mixes comprising a mixture of PCD grades.

With reference to FIG. 3, an example of a PCD element 10 comprises a PCD structure 20 integrally joined to a cemented carbide support body 30. The PCD structure 20 comprises several compressed regions 21 and several tensioned regions 22 in the form of alternating (or inter-leaved) strata or layers. The PCD element 10 may be substantially cylindrical in shape, with the PCD structure 20 located at a working end and defining a working surface 24. The PCD structure 20 may be joined to the support body 30 at a non-planar interface 25. The compressed and tensioned regions 21, 22 have a thickness in the range from about 30 microns to about 200 or, in some embodiments, 300 microns and may be arranged substantially parallel to the working surface 24 of the PCD structure 20. A substantially annular region 26 may be located around a non-planar feature 31 projecting from the support body 30. In some embodiments, the annular region 26 comprises PCD grade II, the tensioned regions 22 comprise PCD grade II and the compressed regions 21 comprise PCD grade III.

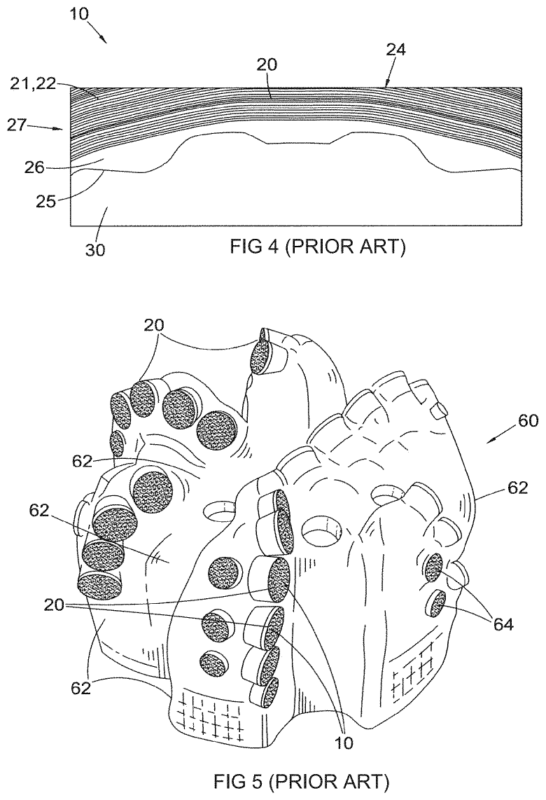

With reference to FIG. 4, an example of a PCD element 10 comprises a PCD structure 20 integrally joined to a cemented carbide support body 30 at a non-planar interface 25 opposite a working surface 24 of the PCD structure 20. The PCD structure 20 may comprise about 10 to 20 alternating compressed and tensioned regions 21, 22 in the form of extended strata or layers. A region 26 that, in this embodiment, does not contain strata may be located adjacent the interface 25. The strata 21, 22 may be curved or bowed and yet generally aligned with the interface 25, and may intersect a side surface 27 of the PCD structure. Some of the strata may intersect the working surface 24.

In some embodiments, the region 26 may be of a substantially greater thickness than the individual strata or layers 21, 22 and, in some embodiments, the thickness of the region comprising the alternating layers 21, 22 may be of a greater thickness than the thickness of the region 26 adjacent the cemented carbide support body 30 which forms a substrate for the PCD material.

In some embodiments, the region 26 adjacent the support body 30 may include multiple layers or strata (not shown) that are of substantially greater thickness than the individual layers or strata 21, 22, for example, the layers 21, 22 may have a thickness in the range from about 30 to 200 microns, and the layers in the region 26 adjacent the support body 30 may have a thickness of greater than about 200 microns.

In some embodiments, the tensioned regions 22 may comprise PCD grade I and the compressed regions 22 may comprise PCD grade III. In another variant, the tensioned regions 22 may comprise PCD grade II and the compressed regions 22 comprise PCD grade III.

In some embodiments, such as those shown in FIGS. 1 to 4, the alternating strata, 21, 22 may have a thickness or thicknesses in the range of from about 5 to 300 microns with the diamond material being formed of PCD with two or more different average diamond grain sizes. For example, strata 21 may be formed of a diamond mix having average diamond grain sizes A and B and strata 22 may also be formed of a diamond mix having average diamond grain sizes A and B but in a different ratio to that of strata 21. In an alternative embodiment, the strata 21 may be formed of a diamond mix having average diamond grain sizes A and B and the strata 22 may be formed of a diamond mix having an average diamond grain size C. It will be appreciated that any other sequence/mixture of two or more diamond grain sizes may be used to form the alternating layers 21, 22. In these embodiments, the region 26 adjacent the support body 30 may be formed of a single layer substantially thicker than the individual strata 21, 22, for example, greater than around 200 microns. Alternatively, the region 26 may be formed of multiple layers, individual layers or strata comprising diamond grains of average grain size A, B, or C as used to form the diamond mixes of the strata 21, 22 or another material or diamond grain size may be used to form the layers in this region 26 adjacent the support body 30.

In some embodiments, the diamond layers or strata 21, 22 and/or strata formed in region 26 adjacent the support body 30 (not shown), may include, for example, one or more of additions such as salt systems, borides, metal carbides of Ti, V, Nb or any of the metals Pd or Ni.

In some embodiments, the strata 21, 22 and/or strata formed in region 26 adjacent the support body 30 may lie in a plane substantially perpendicular to the plane through which the longitudinal axis of the diamond construction 10 extends. The strata may be planar, curved, bowed, domed or distorted, for example, as a result of being subjected to ultra-high pressure during sintering. Alternatively, the alternating strata 21, 22 may be aligned at a predetermined angle to the plane through which the longitudinal axis of the diamond construction 10 extends to influence performance through crack propagation control.

With reference to FIG. 5, an example of a drill bit 60 for drilling into rock (not shown) is shown as comprising example PCD elements 10 mounted onto a bit body 62. The PCD elements 10 are arranged so that the respective PCD structures 20 project from the bit body 62 for cutting the rock.

An example method for making a PCD element is now described. Aggregate masses in the form of sheets containing diamond grains held together by a binder material may be provided. The sheets may be made by a method known in the art, such as by extrusion or tape casting methods, in which slurries comprising diamond grains having respective size distributions suitable for making the desired respective PCD grades, a sintering additive in the form of nano diamond powder or grains and a binder material is spread onto a surface and allowed to dry. Other methods for making diamond-containing sheets may also be used, such as described in U.S. Pat. Nos. 5,766,394 and 6,446,740. Alternative methods for depositing diamond-bearing layers include spraying methods, such as thermal spraying. The binder material may comprise a water-based organic binder such as methyl cellulose or polyethylene glycol (PEG) and different sheets comprising diamond grains having different size distributions, diamond content or additives may be provided. For example, at least two sheets comprising diamond having different mean sizes may be provided and first and second sets of discs may be cut from the respective first and second sheets. The sheets may also contain catalyst material for diamond, such as cobalt, and/or additives for inhibiting abnormal growth of the diamond grains or enhancing the properties of the PCD material. For example, the sheets may contain about 0.5 weight percent to about 5 weight percent of vanadium carbide, chromium carbide or tungsten carbide. In one example, each of the sets may comprise about 10 to 20 discs.

In one embodiment, the binder material is combined with a first fraction of coarser diamond particles or grains and a second fraction of nano-sized diamond particles or grains in powder form. It may be mixed in a conventional mixing process such as, for example, a planetary ball milling process, typically in the presence of a milling aid such as an alcohol for example, methanol. Milling balls, such as Co—WC milling balls, are used to mill the binder and diamond powders together. The binder and diamond mixture is then typically dried at a temperature of 50 to 100° C. to remove the milling aid such as alcohol and other volatile residues and water, for example by freeze drying the mixture. The resultant aggregated mass may then be consolidated into a green body ready for sintering in which it forms one or more layers or strata to be alternated with other layers or strata which may or may not include the nano diamond additions as a sintering additive or, in some embodiments, it is used to form a non-layered region which is to be attached to a layered region during sintering.

The assembly of aggregated mass and substrate may be encapsulated in a capsule suitable for an ultra-high pressure furnace apparatus capable of subjecting the capsule to a pressure of greater than around 5.5 GPa. Various kinds of ultra-high pressure apparatus are known and can be used, including belt, toroidal, cubic and tetragonal multi-anvil systems. The temperature of the capsule should be high enough for the source of catalyst material to melt and low enough to avoid substantial conversion of diamond to graphite. The time should be long enough for sintering to be completed and for the entire sintering additive to be consumed.

Prior to contact with the binder material, the diamond particles of the coarser fraction may have an average particle size ranging from about 0.1 microns to about 50 microns.

A support body comprising cemented carbide in which the cement or binder material comprises a catalyst material for diamond, such as cobalt, may be provided. The support body may have a non-planar end or a substantially planar proximate end on which the PCD structure is to be formed and which forms the interface. A non-planar shape of the end may be configured to reduce undesirable residual stress between the PCD structure and the support body. A cup may be provided for use in assembling the diamond-containing sheets onto the support body. The first and second sets of discs may be stacked into the bottom of the cup in alternating order. In one version of the method, a layer of substantially loose diamond grains may be packed onto the uppermost of the discs. The support body may then be inserted into the cup with the proximate end going in first and pushed against the substantially loose diamond grains, causing them to move slightly and position themselves according to the shape of the non-planar end of the support body to form a pre-sinter assembly.

The green body, once formed as a pre-sinter assembly may be placed into a capsule for an ultra-high pressure press and subjected to an ultra-high pressure of at least about 5.5 GPa and a high temperature of at least about 1,300 degrees centigrade to sinter the diamond grains and form a PCD element comprising a PCD structure integrally joined to the support body. Sintering is carried out for a time sufficient for all of the nano-sized diamond particles or grains which are present as a sintering additive to be consumed, such that substantially no nano-structures are to be found in the sintered PCD material.

In one version of the method, when the pre-sinter assembly is treated at the ultra-high pressure and high temperature, the binder material within the support body melts and infiltrates the strata of diamond grains. The presence of the molten catalyst material from the support body is likely to promote the sintering of the diamond grains by intergrowth with each other to form an integral, stratified PCD structure.

In some embodiments, the diamond grain sizes in the sintered PCD may range from about 0.1 microns to about 50 microns, or from about 0.2 microns to about 10 microns, or from about 0.9 microns to about 2 microns.

As mentioned above, in some versions of the method, the aggregate masses may comprise substantially loose diamond grains, or diamond grains held together by a binder material. The aggregate masses may be in the form of granules, discs, wafers or sheets, and may contain catalyst material for diamond and the nano diamond as a sintering additive.

In one version, the first mean size may be in the range from about 0.1 micron to about 15 microns, and the second mean size may be in the range from about 10 microns to about 40 microns.

As mentioned above, the PCD element so formed may be backed by a substrate, and the binder may be infiltrated from the substrate during HPHT synthesis, or be infiltrated from a shim, foil or layer of alternative binder material at the interface between the PCD layer and the substrate. In some embodiments, the PCD element may be unbacked, in which case the binder may be introduced via known methods in the art such as mixing, milling or coating of the diamond powder with the binder material, or may be infiltrated from a substrate, foil, layer or shim which may be removed after sintering. In some embodiments the PCD element may be leached or partially leached and in other embodiments it may be unleached. The binder may, for example be Co—WC or another binder material known in the art such as for example Ni, Pd, Mn or Fe or combinations of these. The interface between the PCD table and the substrate may be planar or non-planar/shaped. Furthermore, in some embodiments, the PCD table may have a chamfered edge.

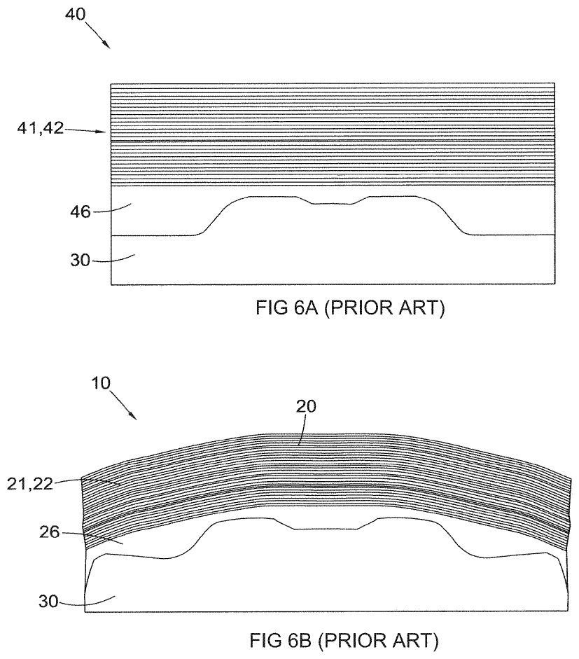

With reference to FIG. 6A, an example of a pre-sinter assembly 40 for making a PCD element may comprise a support body 30, a region 46 comprising diamond grains packed against a non-planar end of the support body 30, and a plurality of alternating diamond-containing aggregate masses in the general form of discs or wafers 41, 42 stacked on the region 46. In some versions, the aggregate masses may be in the form of loose diamond grains or granules. The pre-sinter assembly may be heated to remove the binder material comprised in the stacked discs.

With reference to FIG. 6B, an example of a PCD element 10 comprises a PCD structure 20 comprising a plurality of alternating strata 21, 22 formed of different respective grades of PCD material, and a portion 26 that does not comprise strata. The portion 26 may be cooperatively formed according to the shape of the non-planar end of the support body 30 to which it has integrally bonded during the treatment at the ultra-high pressure. The alternating strata 21, 22 of different grades of PCD or mixes of diamond grain sizes or grades are bonded together by direct diamond-to-diamond intergrowth to form an integral, solid and stratified PCD structure 20. The shapes of the PCD strata 21, 22 may be curved, bowed or distorted in some way as a result of being subjected to the ultra-high pressure. In some versions of the method, the aggregate masses may be arranged in the pre-sinter assembly to achieve various other configurations of strata within the PCD structure, taking into account possible distortion of the arrangement during the ultra-high pressure and high temperature treatment.

The strata 21, 22 may comprise different respective PCD grades as a result of the different mean diamond grain sizes of the strata. Different amounts of catalyst material may infiltrate into the different types of discs 41, 42 comprised in the pre-sinter assembly since they comprise diamond grains having different mean sizes, and consequently different sizes of spaces between the diamond grains. The corresponding alternating PCD strata 21, 22 may thus comprise different, alternating amounts of catalyst material for diamond. The content of the filler material in terms of volume percent within the tensioned region may be greater than that within each of the compressed regions.

In one example, the compressed strata may comprise diamond grains having mean size greater than the mean size of the diamond grains of the tensioned strata. For example, the mean size of the diamond grains in the tensioned strata may be at most about 10 microns, at most about 5 microns or even at most about 2 microns, and at least about 0.1 microns or at least about 1 micron. In some embodiments, the mean size of the diamond grains in each of the compressed strata may be at least about 5 microns, at least about 10 microns or even at least about 15 microns, and at most about 30 microns or at most about 50 microns.

Whilst not wishing to be bound by a particular theory, when the stratified PCD structure is allowed to cool from the high temperature at which it was formed, the alternating strata containing different amounts of metal catalyst material may contract at different rates. This may be because metal contracts much more substantially than diamond does as it cools from a high temperature. This differential rate of contraction may cause adjacent strata to pull against each other, thus inducing opposing stresses in them.

The PCD element 10 described with reference to FIG. 6B may be processed by grinding to modify its shape to form a PCD element substantially as described with reference to FIG. 4. This may involve removing part of some of the curved strata to form a substantially planar working surface and a substantially cylindrical side surface. Catalyst material may be removed from a region of the PCD structure adjacent the working surface or the side surface or both the working surface and the side surface. This may be done by treating the PCD structure with acid to leach out catalyst material from between the diamond grains, or by other methods such as electrochemical methods. A thermally stable region, which may be substantially porous, extending a depth of at least about 50 microns or at least about 100 microns from a surface of the PCD structure, may thus be provided. Some embodiments with 50 to 80 micron thick layers in which this leach depth is around 250 microns have been shown to exhibit substantially improved performance, for example a doubling in performance after leaching over an unleached PCD product. In one example, the substantially porous region may comprise at most 2 weight percent of catalyst material.

The use of alternating layers or strata with different grain sizes through, for example, differences in binder content, may controllably give a different structure when acid leaching is applied to the PCD construction 10, especially for the embodiments in which the binder does not contain V and/or Ti. Such a structure may be created as a result of different residual tungsten in each layer during HCl acid leaching. In essence, the rate of leaching is likely to be different in each layer (unless HF-containing acid is used) and this may enable preferential leaching especially at the edges of the PCD material. This may be more pronounced for layers thicker than 120 microns. This is unlikely to occur if HF acid leaching were applied to the PCD material. The reason for this is that, in such a process, the HCl acid removes Co and leaves behind tungsten, whilst HF acid leaching would remove everything in the binder composition.

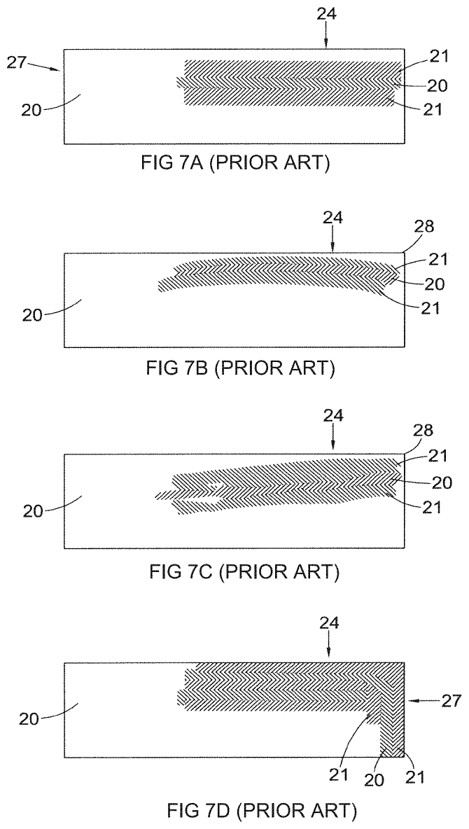

With reference to FIG. 7A, an example variant of a PCD structure 20 comprises at least three substantially planar strata 21, 22 strata arranged in an alternating configuration substantially parallel to a working surface 24 of the PCD structure 20 and intersecting a side surface 27 of the PCD structure.

With reference to FIG. 7B, an example variant of a PCD structure 20 comprises at least three strata 21, 22 strata arranged in an alternating configuration, the strata having a curved or bowed shape, with at least part of the strata inclined away from a working surface 24 and cutting edge 28 of the PCD structure.

With reference to FIG. 7C, an example variant of a PCD structure 20 comprises at least three strata 21, 22 strata arranged in an alternating configuration, at least part of the strata inclined away from a working surface 24 of the PCD structure and extending generally towards a cutting edge 28 of the PCD structure.

With reference to FIG. 7D, an example variant of a PCD structure 20 comprises at least three strata 21, 22 strata arranged in an alternating configuration, at least part of some of the strata being substantially aligned with a working surface 24 of the PCD structure and at least part of some of the strata generally aligned with a side surface 27 of the PCD structure. Strata may be generally annular of part annular and substantially concentric with a substantially cylindrical side surface 27 of the PCD structure 20.

The PCD structure may have a surface region proximate a working surface, the region comprising PCD material having a Young's modulus of at most about 1,050 MPa, or at most about 1,000 MPa. The surface region may comprise thermally stable PCD material.

Some examples of PCD structures may have at least 3, at least 5, at least 7, at least 10 or even at least 15 compressed regions, with tensioned regions located between them.

Each stratum or layer may have a thickness of at least about 5 microns, in other embodiments at least about 100 microns, or in other embodiments at least about 200 microns. Each stratum or layer may, for example, have a thickness of at most about 300 microns or at most about 500 microns. In some example embodiments, each stratum or layer may have a thickness of at least about 0.05 percent, at least about 0.5 percent, at least about 1 percent or at least about 2 percent of a thickness of the PCD structure measured from a point on a working surface at one end to a point on an opposing surface. In some embodiments, each stratum or layer may have a thickness of at most about 5 percent of the thickness of the PCD structure.

As used herein, the term “residual stress state” refers to the stress state of a body or part of a body in the absence of an externally-applied loading force. The residual stress state of a PCD structure, including a layer structure may be measured by means of a strain gauge and progressively removing material layer by layer. In some examples of PCD elements, at least one compressed region may have a compressive residual stress of at least about 50 MPa, at least about 100 MPa, at least about 200 MPa, at least about 400 MPa or even at least about 600 MPa. The difference between the magnitude of the residual stress of adjacent strata may be at least about 50 MPa, at least about 100 MPa, at least about 200 MPa, at least about 400 MPa, at least about 600 MPa, at least about 800 MPa or even at least about 1,000 MPa. In one example, at least two successive compressed regions or tensioned regions may have different residual stresses. The PCD structure may comprise at least three compressed or tensioned regions each having a different residual compressive stress, the regions arranged in increasing or decreasing order of compressive or tensile stress magnitude, respectively.

In one example, each of the regions may have a mean toughness of at most 16 MPa·m^{1/2}. In some embodiments, each of the regions may have a mean hardness of at least about 50 GPa, or at least about 60 GPa. Each of the regions may have a mean Young's modulus of at least about 900 MPa, at least about 950 MPa, at least about 1,000 or even at least about 1,050 MPa.

As used herein, “transverse rupture strength” (TRS) is measured by subjecting a specimen in the form of a bar having width W and thickness T to a load applied at three positions, two on one side of the specimen and one on the opposite side, and increasing the load at a loading rate until the specimen fractures at a load P. The TRS is then calculated based on the load P, dimensions of the specimen and the span L, which is the distance between the two load positions on one side. Such a measurement may also be referred to as a three-point bending test and is described by D. Munz and T. Fett in “Ceramics, mechanical properties, failure behaviour, materials selection” (1999, Springer, Berlin). The TRS corresponding to a particular grade of PCD material is measured measuring the TRS of a specimen of PCD consisting of that grade.

While the provision of a PCD structure with PCD strata having alternating compression and tensile stress states tends to increase the overall effective toughness of the PCD structure, this may have the effect of increasing the potential incidence of de-lamination, in which the strata may tend to come apart. While wishing not to be bound by a particular theory, de-lamination may tend to arise if the PCD strata are not sufficiently strong to sustain the residual stress between them. This effect may be ameliorated by selecting the PCD grades, and the PCD grade of which the tensioned region in particular is formed, to have sufficiently high TRS. The TRS of the PCD grade or grades of which the tensioned region is formed should be greater than the residual tension that it may experience. One way of influencing the magnitude of the stress that a region may experience is by selecting the relative thicknesses of adjacent regions. For example, by selecting the thickness of a tensioned region to be greater than that of the adjacent compressive regions is likely to reduce the magnitude of tensile stress within the tensioned region.

The residual stress states of the regions may vary with temperature. In use, the temperature of the PCD structure may differ substantially between points proximate a cutting edge and points remote from the cutting edge. In some uses, the temperature proximate the cutting edge may reach several hundred degrees centigrade. If the temperature exceeds about 750 degrees centigrade, diamond material in the presence of catalyst material such as cobalt is likely to convert to graphite material, which is not desired. Therefore, in some uses, the alternating stress states in adjacent regions as described herein should be considered at a temperature of up to about 750 degrees centigrade.

The K₁C toughness of a PCD disc is measured by means of a diametral compression test, which is described by Lammer (“Mechanical properties of polycrystalline diamonds”, Materials Science and Technology, volume 4, 1988, p. 23.) and Miess (Miess, D. and Rai, G., “Fracture toughness and thermal resistances of polycrystalline diamond compacts”, Materials Science and Engineering, 1996, volume A209, number 1 to 2, pp. 270-276).

Young's modulus is a type of elastic modulus and is a measure of the uni-axial strain in response to a uni-axial stress, within the range of stress for which the material behaves elastically. A preferred method of measuring the Young's modulus E is by means of measuring the transverse and longitudinal components of the speed of sound through the material, according to the equation E=2ρ·C_{T}²(1+v), where v=(1−2 (C_{T}/C_{L})²)/(2−2 (C_{T}/C_{L})²), C_{L} and C_{T} are respectively the measured longitudinal and transverse speeds of sound through it and ρ is the density of the material. The longitudinal and transverse speeds of sound may be measured using ultrasonic waves, as is well known in the art. Where a material is a composite of different materials, the mean Young's modulus may be estimated by means of one of three formulas, namely the harmonic, geometric and rule of mixtures formulas as follows: E=1/(f₁/E₁+f₂/E₂)); E=E₁^{f1}+E₁^{f2}; and E=E₁+f₂ E₂, in which the different materials are divided into two portions with respective volume fractions of f₁ and f₂, which sum to one.

A non-limiting example PCD element comprising alternating strata of two different grades of PCD was provided as follows.

First and second sheets, each containing diamond grains having a different mean size from each other and held together by an organic binder were made by the tape casting method. In this example, nano diamond additions to act as a sintering additive were included in both the first and second sheets although in other embodiments they may be included in one or other of the two sheets. The first sheet was formed from 1 g of UDD which was added to 99 g of a bimodal diamond powder to form an aggregated mass which was ball milled in 10 ml of methanol with Co—WC milling balls. The ratio of milling balls:powder was 4:1 and the milling was carried out at 90 rpm for 1 hour. This mix was formed into a sheet using the tape casting method. This method involved providing respective slurries of diamond grains suspended in liquid binder, casting the slurries into sheet form and allowing them to dry to form self-supportable diamond-containing sheets. The mean size of the diamond grains, excluding the grain sizes of the nano diamond additions, within the first sheet was in the range from about 5 microns to about 14 microns, and the mean size of the diamond grains within the second sheet was in the range from about 18 microns to about 25 microns. Both sheets also contained about 3 weight percent vanadium carbide and about 1 weight percent cobalt. After drying, the sheets were about 0.12 mm thick. Fifteen circular discs having diameter of about 18 mm were cut from each of the sheets to provide first and seconds sets of disc-shaped wafers.

A support body formed of cobalt-cemented tungsten carbide was provided. The support body was generally cylindrical in shape, having a diameter of about 18 mm and a non-planar end formed with a central projecting member. A metal cup having an inner diameter of about 18 mm was provided for assembling a pre-sinter assembly. The diamond-containing wafers were placed into the cup, alternately stacked on top of each other with discs from the first and second sets inter-leaved. A layer of loose diamond grains having a mean size in the range from about 18 microns to about 25 microns was placed into the upturned cup, on top of the uppermost of the wafers, and the support body was inserted into the cup, with the non-planar end pushed against the layer.

The pre-sinter assembly thus formed was assembled into a capsule for an ultra-high pressure press and subjected to a pressure of about 6.8 GPa and a temperature of at least about 1,450 degrees centigrade for about 10 minutes dwell time at maximum temperature to sinter the diamond grains and form a PCD element comprising a PCD structure bonded to the support body. The PCD cutter was recovered and processed.

The PCD element was processed by grinding and lapping to form a cutter element having a substantially planar working surface and cylindrical side.

In a further example, a further PCD cutter was formed using 1 g of crushed nano diamond which was added to 99 g of a bimodal diamond powder. The same process described above was applied to create the further PCD cutter.

As used herein, the expression “formed of” means “consists of, apart from possible minor or non-substantial deviations in composition or microstructure”.

In some embodiments, the body of PCD material has a diamond content of from 80 to 95 volume percent and a binder content of at least 5 volume percent, and comprises diamond grains having a mean diamond grain contiguity of greater than 60 percent and a standard deviation of less than 2.2 percent, measure using the technique explained below. The diamond grains form a skeletal mass defining interstices or interstitial regions between them. The combined lengths of lines passing through all points lying on all bond or contact interfaces between diamond grains within a section of the PCD material are summed to determine the diamond perimeter, and the combined lengths of lines passing through all points lying on all interfaces between diamond and interstitial regions within a section of the PCD material are summed to determine the binder perimeter.

In the field of quantitative stereography, particularly as applied to cemented carbide material, “contiguity” is understood to be a quantitative measure of inter-phase contact. It is defined as the internal surface area of a phase shared with grains of the same phase in a substantially two-phase microstructure (Underwood, E.E, “Quantitative Stereography”, Addison-Wesley, Reading MA 1970; German, R. M. “The Contiguity of Liquid Phase Sintered Microstructures”, Metallurgical Transactions A, Vol. 16A, July 1985, pp. 1247-1252). As used herein, “diamond grain contiguity” is a measure of diamond-to-diamond contact or bonding, or a combination of contact and bonding within PCD material.

As used herein, “diamond grain contiguity” κ may be calculated according to the following formula using data obtained from image analysis of a polished section of PCD material:

κ=100*[2*(δ−β)]/[(2*(δ−β))+δ], where δ is the diamond perimeter, and β is the binder perimeter.

As used herein, the diamond perimeter is the fraction of diamond grain surface that is in contact with other diamond grains. It is measured for a given volume as the total diamond-to-diamond contact area divided by the total diamond grain surface area. The binder perimeter is the fraction of diamond grain surface that is not in contact with other diamond grains. In practice, measurement of contiguity is carried out by means of image analysis of a polished section surface. The combined lengths of lines passing through all points lying on all diamond-to-diamond interfaces within the analysed section are summed to determine the diamond perimeter, and analogously for the binder perimeter.

Images used for the image analysis should be obtained by means of scanning electron micrographs (SEM) taken using a backscattered electron signal. Optical micrographs may not have sufficient depth of focus and may give substantially different contrast. The method of measuring diamond grain contiguity requires that distinct diamond grains in contact with or bonded to each other can be distinguished from single diamond grains. Adequate contrast between the diamond grains and the boundary regions between them may be important for the measurement of contiguity since boundaries between grains may be identified on the basis of grey scale contrast. Boundary regions between diamond grains may contain included material, such as catalyst material, which may assist in identifying the boundaries between grains.

A multimodal size distribution of a mass of grains is understood to mean that the grains have a size distribution with more than one peak, each peak corresponding to a respective “mode”. Multimodal polycrystalline bodies are typically made by providing more than one source of a plurality of grains, each source comprising grains having a substantially different average size, and blending together the grains. Measurement of the size distribution of the blended grains may reveal distinct peaks corresponding to distinct modes. When the grains are sintered together to form the polycrystalline body, their size distribution is further altered as the grains are compacted against one another and fractured, resulting in the overall decrease in the sizes of the grains. Nevertheless, the multimodality of the grains may still be clearly evident from image analysis of the sintered article.

Unless otherwise stated herein, dimensions of size, distance, and perimeter and so forth relating to grains and interstices within PCD material, as well as the grain contiguity, refer to the dimensions as measured on a surface of, or a section through a body comprising PCD material and no stereographic correction has been applied. For example, the size distributions of the diamond grains of embodiments of the invention were measured by means of image analysis carried out on a polished surface, and a Saltykov correction was not applied.

In measuring the mean value and deviation of a quantity such as grain contiguity, or other statistical parameter measured by means of image analysis, several images of different parts of a surface or section are used to enhance the reliability and accuracy of the statistics. The number of images used to measure a given quantity or parameter may be at least about 9 or even up to about 36. The number of images used may be, for example, about 16. The resolution of the images needs to be sufficiently high for the inter-grain and inter-phase boundaries to be clearly made out. In the statistical analysis, typically 16 images are taken of different areas on a surface of a body comprising the PCD material, and statistical analyses are carried out on each image as well as across the images. Each image should contain at least about 30 diamond grains, although more grains may permit more reliable and accurate statistical image analysis.

Diamond contiguity is an important performance indicator, as it indicates the degree of intergrowth or bonding between the diamond particles, and all else being equal the higher the diamond contiguity the better the cutter performance. Higher diamond contiguity is normally associated with high diamond content which in turn results in lower binder content, as the high diamond content translates into low porosity and therefore low binder content, as the binder occupies the pores.

According to classic materials science of composite materials, low binder content results in low fracture toughness, as it is normally the hard grains (in this case diamond) that imparts hardness to the composite material, and the more ductile binder (in PCD, normally Co—WC) that imparts toughness to the composite material.

Therefore, high diamond content and low binder content are expected to be associated with increased hardness and decreased toughness, so that failure due to fracture or spelling of the PCD is expected to increase.

It was therefore surprising to find that PCD with improved wear performance may be obtained by adding nanodiamond particles to the green body prior to sintering at HPHT. The nanodiamond particles are not evident in the final product, so they perform the role of a sacrificial sintering additive. Using a nanodiamond additive in this way results in an unusual combination of diamond content, binder content and diamond contiguity, enabling an increase in diamond contiguity combined with a decrease in diamond content and an increase in binder content. This unusual combination is expected to result in improved wear performance without compromising toughness.

Wishing not to be bound by theory, due to its very small particle size, nanodiamond has a higher solubility than larger, micron-sized diamond, and it is believed that it is this property that makes it an effective sintering additive. During the HPHT sintering cycle, the nanodiamond is believed to dissolve preferentially to the larger diamond particles, probably dissolving sooner and resulting in a higher carbon concentration dissolved in the molten metal than would be the case with the larger diamond particles. As it dissolves sooner, less of the original large tightly packed diamond particles are lost to dissolution, and the higher carbon concentration in the molten metal means a higher supersaturation level is obtained which facilitates crystallisation or precipitation of the dissolved carbon as newly formed diamond that bonds the diamond particles together.

The solubility of carbon in cobalt may be expressed by the following formula:

(C/Co)=exp[(2ysl×Vm)/RT×1/r], where:

ysl=interfacial energy

Vm=molar volume

R=gas constant

T=Temperature.

As the grain size decreases, the solubility of carbon in cobalt increases. The solubility of the nanodiamond in a cobalt matrix is extreme, and according to the above equation, it will be consumed during the sintering process.

The diamond contiguity for the PCD containing crushed nanodiamond as the source of nano diamond in the sintering mixture was found to be much higher than the standard base PCD. A combination of the image analysis data and a known abrasion test shows that the sample having a higher diamond contiguity performed better in an abrasion test.

The following clauses set out some of the possible combinations envisaged by the disclosure:
1. A PCD structure comprising a first layer or strata, a second layer or strata and a third layer or strata; the second layer or strata disposed between and bonded to the first and third layers or strata by intergrowth of diamond grains; each layer or strata being formed of a respective PCD grade or grades having a TRS of at least 1,200 MPa or at least 1,600 MPa; the PCD grade or grades comprised in the second layer or strata having a higher coefficient of thermal expansion (CTE) than the respective PCD grades of the first and third layers or strata. The second layer or strata may comprise a PCD grade or grades having a CTE of at least 4×10⁻⁶ mm/° C.
2. A PCD structure comprising a first and a third layer or strata, each in a respective state of residual compressive stress, and a second layer or strata in a state of residual tensile stress and disposed between the first and third layer or strata; the first, second and third layers or strata each formed of one or more respective PCD grades and directly bonded to each other by intergrowth of diamond grains; the PCD grades having transverse rupture strength (TRS) of at least 1,200 MPa.
3. A PCD structure comprising a first layer or strata, a second layer or strata and a third layer or strata; the second layer or strata being disposed between and bonded to the first and third layers or strata by intergrowth of diamond grains; each region formed of one or more respective PCD grades comprising at least 85 volume percent diamond grains having a mean size of at least 0.1 micron and at most 30 micron; the PCD grade or grades comprised in the second layer or strata containing a higher content of metal than is contained in each of the respective PCD grades comprised in the first and in the third layers or strata. The PCD grade or grades comprised in the second layer or strata may contain at least 9 volume percent metal.
4. A PCD structure comprising a first layer or strata, a second layer or strata and a third layer or strata; the second layer or strata being disposed between and bonded to the first and third layers or strata by intergrowth of diamond grains; each layer or strata being formed of one or more respective PCD grades having a TRS of at least 1,200 MPa; the PCD grade or grades comprised in the second layer or strata containing more metal than is contained in each of the respective PCD grades comprised in the first and in the third layers or strata. The PCD grade or grades comprised in the second layer or strata may contain at least 9 volume percent metal.
5. In all of the combinations above numbered from 1 to 4, the PCD structure may comprise a thermally stable region extending a depth of at least 50 microns from a surface of the PCD structure; in which the thermally stable region comprises at most 2 weight percent of catalyst material for diamond.
6. In all of the combinations above numbered from 1 to 5, the layers or strata may be in the form of strata arranged in an alternating configuration to form an integral, stratified PCD structure. The strata may have thickness of at least about 10 microns and at most about 500 microns, and the strata may be generally planar, curved, bowed or domed.
7. In all of the combinations above numbered from 1 to 6, the layers or strata may intersect a working surface or side surface of the PCD structure. The PCD grade or grades comprised in the first and third layers or strata may comprise diamond grains having a different mean size than the diamond grains comprised in the second layer or strata.
8. In all of the combinations above numbered from 1 to 7, the volume or thickness of the second layer or strata may be greater than the volume or thickness of the first layer or strata and the volume or thickness of the third layer or strata.

Various modifications will be appreciated to the embodiments described which are not intended to be limiting. For example, whilst the subsequent processing of the PCD element 10 such as leaching to remove catalyst material therefrom has been described with reference to the embodiment shown in FIG. 6B, such processing techniques could be applied to any of the embodiments. Also, the PCD element so formed may be substantially cylindrical and have a substantially planar working surface, or may be, for example, a generally domed, pointed, rounded conical or frusto-conical working surface. Furthermore, the PCD element may be used, in some embodiments, for a rotary shear (or drag) bit for boring into the earth, for a percussion drill bit or for a pick for mining or asphalt degradation. In some embodiments, PCD elements as described herein may have the aspect of enhanced resistance to fracture.

1. A polycrystalline diamond structure comprising a first region and a second region adjacent the first region, the second region being bonded to the first region by intergrowth of diamond grains, the first region comprising a plurality of alternating strata or layers, each or one or more strata or layers in the first region having a thickness in the range of around 5 to 300 microns; wherein the polycrystalline diamond (PCD) structure has a diamond content of at most about 95 percent of the volume of the PCD material, a binder content of at least about 5 percent of the volume of the PCD material, and one or more of the layers or strata in the first region comprise and/or the second region comprises diamond grains having a mean diamond grain contiguity of greater than about 60 percent and a standard deviation of less than about 2.2 percent.

2. A PCD structure according to claim 1, wherein each stratum or layer in the first region has a thickness in the range of around 30 to 300 microns.

3. A PCD structure according to claim 1, wherein one or more of the strata or layers in the first region have a thickness in the range of around 30 to 200 microns.

4. A PCD structure according to claim 1, wherein the second region comprises a plurality of layers or strata.

5. A PCD structure according to claim 4, wherein one or more strata or layers in the second region having a thickness greater than the thicknesses of the individual strata or layers in the first region, wherein the alternating layers or strata in the first region comprise first layers or strata alternating with second layers or strata, the first layers or strata being in a state of residual compressive stress and the second layers or strata being in a state of residual tensile stress; and one or more of the layers or strata in the first and/or second regions comprise diamond grains having a mean diamond grain contiguity of greater than about 60 percent and a standard deviation of less than about 2.2 percent.

6. A polycrystalline diamond structure according to claim 4, wherein the strata or layers in the second region have a thickness of greater than around 200 microns.

7. A PCD structure according to claim 4, wherein each stratum or layer in the first and/or second region has a substantially uniform diamond grain size distribution throughout said stratum or layer.

8. A PCD structure according to claim 4, wherein the layers or strata in the second region comprise diamond grains of a predetermined average grain size.

9. A PCD structure according to claim 8, wherein the predetermined average grain size of the diamond grains in the second region is one of the average grain sizes of the diamond grains in the mix of diamond grains in the first region.

10. A PCD structure according to claim 4, wherein layers or strata in the second region comprise one or more of:
salt systems;
borides or metal carbides of at least one of Ti, V, or Nb; or
at least one of the metals Pd or Ni.

11. A PCD structure according to claim 4, wherein the PCD structure has a longitudinal axis, the layers or strata in the second region lying in a plane substantially perpendicular to the plane through which the longitudinal axis of the PCD structure extends.

12. A PCD structure according to claim 4, wherein the PCD structure has a longitudinal axis, the layers or strata in the first region and/or the second region lying in a plane at an angle to the plane through which the longitudinal axis of the PCD structure extends.

13. A PCD structure according to claim 1, wherein the alternating layers or strata comprise first layers or strata alternating with second layers or strata, the first layers or strata being in a state of residual compressive stress and the second layers or strata being in a state of residual tensile stress.

14. A PCD structure according to claim 1, wherein the first region comprises one or more strata or layers having two or more different average diamond grain sizes.

15. A PCD structure according to claim 1, wherein the first region comprises one or more strata or layers having three or more different average diamond grain sizes.

16. A PCD structure according to claim 1, wherein the first region comprises an external working surface forming the initial working surface of the PCD structure in use.

17. A PCD structure according to claim 1, wherein the second region has a thickness greater than the thickness of the individual strata or layers in the first region.

18. A PCD structure according to claim 1, wherein the alternating layers or strata comprise first layers or strata alternating with second layers or strata, the first layers or strata comprising diamond grains and the second layers or strata comprising diamond grains.

19. A PCD structure according to claim 1, wherein each stratum or layer is formed of one or more respective PCD grades having a TRS of at least 1,000 MPa; the PCD grade or grades in adjacent strata or layers having a different coefficient of thermal expansion (CTE).

20. A PCD structure according to claim 19, wherein one or more of the strata or layers comprise a PCD grade or grades having a CTE of at least 3×10⁻⁶ mm/° C.

21. A PCD structure according to claim 1, wherein the alternating layers or strata comprise first layers or strata alternating with second layers or strata, the first layers or strata comprising a mixture of diamond grains having three or more different average diamond grain sizes and the second layers or strata being formed of a mixture of diamond grains having the same three or more average diamond grain sizes, wherein the first strata or layers in the first region have a different ratio of diamond grain sizes in said mixture from the second strata or layers in the first region.

22. A PCD structure according to claim 1, wherein the alternating layers or strata comprise first layers or strata alternating with second layers or strata, the first layers or strata comprising a mixture of diamond grains having a first average grain size or sizes and the second layers or strata comprising a mixture of diamond grains having a second average grain size or sizes.

23. A PCD structure according to claim 1, wherein layers or strata in the first region comprise one or more of:
salt systems;
borides or metal carbides of at least one of Ti, V, or Nb; or
at least one of the metals Pd or Ni.

24. A PCD structure according to claim 1, wherein the PCD structure has a longitudinal axis, the layers or strata in the first region lying in a plane substantially perpendicular to the plane through which the longitudinal axis of the PCD structure extends.

25. A PCD structure according to claim 1, wherein the PCD structure has a longitudinal axis, the layers or strata in the first region and/or the second region lying in a plane at an angle to the plane through which the longitudinal axis of the PCD structure extends.

26. A PCD structure according to claim 1, wherein the layers or strata are substantially planar, curved, bowed or domed.

27. A PCD structure according to claim 1, wherein the volume of the first region is greater than the volume of the second region.

28. A PCD structure according to claim 1, wherein one or more of the strata or layers intersect a working surface or side surface of the PCD structure.

29. A PCD structure as claimed in claim 1, wherein at least a portion of the first region is substantially free of a catalyst material for diamond, said portion forming a thermally stable region.

30. A PCD structure as claimed in claim 29, wherein the thermally stable region extends a depth of at least 50 microns from a surface of the PCD structure.

31. A PCD structure as claimed in claim 29, wherein the thermally stable region comprises at most 2 weight percent of catalyst material for diamond.

32. A PCD structure according to claim 1, wherein the binder material comprises at least 12 volume percent of the PCD material.

33. A PCD structure according to claim 1, wherein the diamond content of the polycrystalline diamond material is at least 80 percent and at most 88 percent of the volume of the polycrystalline diamond material.

34. A PCD compact or construction comprising the PCD structure of claim 1.

35. A wear element comprising a PCD structure according to claim 1.

36. A PCD element for a rotary shear bit for boring into the earth, or for a percussion drill bit, comprising a PCD structure as claimed in claim 1 bonded to a cemented carbide support body.

37. A drill bit or a component of a drill bit for boring into the earth, comprising a PCD element as claimed in claim 36.

38. A method for making a polycrystalline diamond (PCD) structure, the method comprising:
providing a first fraction of diamond particles or grains and a sintering additive, the sintering additive comprising a carbon source of nano-sized particles or grains, and forming the diamond particles and sintering additive into a first aggregated mass,
providing a second fraction of diamond particles or grains and forming into a second aggregated mass;
consolidating the first aggregated mass and a binder material, typically a catalyst material for diamond and the second aggregated mass to form a green body formed of a plurality of alternating layers or strata of the first and second aggregate masses;
and subjecting the green body to conditions of pressure and temperature at which diamond is more thermodynamically stable than graphite and for a time sufficient to consume the sintering additive, sintering it and forming a body of polycrystalline diamond material that is:
thermodynamically and crystallographically stable,
substantially devoid of any nano-structures, the body of polycrystalline diamond (PCD) material having a diamond content of at most about 95 percent of the volume of the PCD material, a binder content of at least about 5 percent of the volume of the PCD material,
the step of sintering further comprising forming a body of polycrystalline diamond material comprising a first region and a second region adjacent the first region, the second region being bonded to the first region by intergrowth of diamond grains; the first region comprising a plurality of alternating strata or layers, each stratum or layer having a thickness in the range of around 5 to 300 microns; wherein the alternating layers or strata in the first region comprise first layers or strata alternating with second layers or strata, the first layers or strata being in a state of residual compressive stress and the second layers or strata being in a state of residual tensile stress; and wherein and one or more of the layers or strata in the first regions and/or the second region comprise diamond grains having a mean diamond grain contiguity of greater than about 60 percent and a standard deviation of less than about 2.2 percent.

39. A method according to claim 38, wherein the method includes subjecting the green body to a pressure of about 6.0 GPa or more and a temperature of about 1350° C. or more.

40. A method according to claim 38, wherein the PCD material is sintered for a period of 2 minutes to 60 minutes.

41. A method according to claim 38, wherein the diamond particles or grains, prior to contact with the sintering additive or binder material, have an average particle or grain size ranging from about 0.1 microns to about 50 microns.

42. A method according to claim 38, wherein the sintering additive is a nano-sized carbon source selected from the group comprising graphite, soot, coke, carbon anions and fullerenes.

43. A method according to claim 38, wherein the sintering additive is nanodiamond.

44. A method according to claim 43, wherein the nanodiamond is UDD, PDD or a crushed source of nanodiamond.

45. A method according to claim 38, wherein the sintering additive is provided in an amount of from about 0.01 to about 5 wt %, or from about 0.5 to about 1 wt %, or up to about 50 wt %.

46. A method according to claim 38, wherein the binder material is Ni, Pd, Mn or Fe, or combinations of these metal catalysts with one or other of these catalysts and/or with Co.

47. A method according to claim 38, wherein the diamond particles or grains prior to contact with the sintering additive or binder material have an average particle or grain size of from about 0.1 microns to about 50 microns, or from about 0.2 microns to about 10 microns, or from about 0.9 microns to about 2 microns.
